(19) United States
(12) Patent Application Publication
(10) Pub. No.: US 2020/0157300 A1
(43) Pub. Date: May 21, 2020

(54) RESIN COMPOSITION, PREPREG, METAL-CLAD LAMINATE, PRINTED WIRING BOARD, AND METHOD FOR FABRICATING THE METAL-CLAD LAMINATE

(71) Applicant: PANASONIC INTELLECTUAL PROPERTY MANAGEMENT CO., LTD., Osaka (JP)

(72) Inventors: Yohsuke ISHIKAWA, Fukushima (JP); Kazuki MATSUMURA, Mie (JP); Koji KISHINO, Mie (JP)

(73) Assignee: PANASONIC INTELLECTUAL PROPERTY MANAGEMENT CO., LTD., Osaka (JP)

(21) Appl. No.: 16/619,385

(22) PCT Filed: Jun. 4, 2018
(86) PCT No.: PCT/JP2018/021300

§ 371 Date: Dec. 4, 2019

(30) Foreign Application Priority Data
Jun. 8, 2017 (JP) 2017-113826

(51) Int. Cl. C08J 5/24; C08L 63/04; C08L 61/06; B32B 5/02; B32B 15/14; B32B 15/20; H05K 1/03; H05K 3/02

(52) U.S. Cl. CPC C08J 5/24; B32B 2457/08; C08L 61/06; B32B 5/02; B32B 15/14; B32B 15/20; H05K 1/0353; H05K 3/022; C08J 2363/04; C08J 2461/10; C08J 2361/10; C08J 2463/04; B32B 2262/101; B32B 2260/021; B32B 2260/046; C08L 63/04

(57) ABSTRACT

The resin composition includes: an epoxy resin as Component (A); a phenolic compound as Component (B); and an imidazole compound having a triazine skeleton, as Component (C). A cured product of the resin composition has a glass transition temperature of 260° C. or more.

### TECHNICAL FIELD

The present invention generally relates to a resin composition, a prepreg, a metal-clad laminate, a printed wiring board, and a method for fabricating the metal-clad laminate. More particularly, the present invention relates to a resin composition containing an epoxy resin, a prepreg including a dried or semi-cured product of the resin composition, a metal-clad laminate and a printed wiring board each including an insulating layer containing a cured product of the resin composition, and a method for fabricating the metal-clad laminate using the resin composition.

### BACKGROUND ART

A resin composition containing an epoxy resin, a curing agent, a curing accelerator, and other substances is one of materials of an insulating layer for metal-clad laminates and printed wiring boards (see, for example, Patent Literature 1).

Recently, printed wiring boards for use in on-board equipment, among other things, are increasingly required to exhibit excellent thermal resistance.

### CITATION LIST

### Patent Literature

Patent Literature 1: WO 2010/035452 A1

### Summary of Invention

It is an object of the present invention to provide a resin composition containing an epoxy resin and having the ability to turn, when cured, into a cured product with thermal resistance, a prepreg including a dried or semi-cured product of the resin composition, a metal-clad laminate and a printed wiring board each including an insulating layer containing a cured product of the resin composition, and a method for fabricating the metal-clad laminate using the resin composition.

A resin composition according to an aspect of the present invention includes: an epoxy resin as Component (A); a phenolic compound as Component (B); and an imidazole compound having a triazine skeleton, as Component (C). A cured product of the resin composition has a glass transition temperature of 260° C. or more.

A prepreg according to another aspect of the present invention includes: a fibrous base member, and a dried or semi-cured product of the resin composition impregnated into the fibrous base member.

A metal-clad laminate according to still another aspect of the present invention includes; an insulating layer, and a metal layer stacked on the insulating layer. The insulating layer includes a cured product of the resin composition described above.

A printed wiring board according to yet another aspect of the present invention includes: an insulating layer, and conductor wiring laid on top of the insulating layer. The insulating layer includes a cured product of the resin composition described above.

A method for fabricating a metal-clad laminate according to yet another aspect of the present invention includes: forming a layered structure by overlaying a sheet of metallic foil over a prepreg, the prepreg including: a fibrous base member; and a dried or semi-cured product of a resin composition impregnated into the fibrous base member; and forming an insulating layer including the fibrous base member and the cured product of the resin composition and a metal layer of the metallic foil by thermally pressing the layered structure. The resin composition contains: an epoxy resin as Component (A); a phenolic compound as Component (B); and an imidazole compound having a triazine skeleton, as Component (C). A highest heating temperature when the layered structure is thermally pressed is equal to or higher than 280° C.

### DESCRIPTION OF EMBODIMENTS

A resin composition, a prepreg, a cured product, a metal-clad laminate, a printed wiring board, and a method for fabricating the metal-clad laminate according to an exemplary embodiment of the present invention will be described.

The resin composition contains: an epoxy resin as Component (A); a phenolic compound as Component (B); and an imidazole compound having a triazine skeleton, as Component (C). A cured product of the resin composition has a glass transition temperature of 260° C. or more. The glass transition temperature of the cured product may be measured as will be described later in specific examples.

This embodiment achieves the advantage of providing a resin composition having the ability to turn, when cured, into a cured product with thermal resistance, a cured product with thermal resistance, a prepreg including a dried or semi-cured product of the resin composition, a metal-clad laminate and a printed wiring board each including an insulating layer containing a cured product of the resin composition, and a method for fabricating the metal-clad laminate using the resin composition.

The cured product is formed by heating the resin composition, a dried product of the resin composition, or a semi-cured product of the resin composition. The heating needs to be conducted under that the condition that the resin composition is allowed to be sufficiently cured. The resin composition needs to be turned, by being heated under at least one condition, into a cured product having a glass transition temperature of 260° C. The condition for heating the resin composition, a dried product of the resin composition, or a semi-cured product of the resin composition may be, for example, that the highest heating temperature should fall within the range from 260° C. to 400° C., the temperature increase rate from the initial temperature when the resin composition or the dried or semi-cured product thereof starts to be heated to the highest heating temperature should fall within the range of 2° C./sec to 8° C./sec, and the heating duration should fall within the range from 1.5 to 6 minutes. When heating is conducted by thermal pressing, the pressing pressure should fall within the range from 0.5 to 5 MPa. A cured product obtained by heating the resin composition under any of the conditions falling within these ranges suitably has a glass transition temperature of 260° C. or more.

An insulating layer for a metal-clad laminate and a printed wiring board may be formed out of the resin composition. This allows the resin composition to improve the thermal resistance of the insulating layer.

Note that an imidazole compound having a triazine skeleton is known in the art. For example, PCT International Application Publication WO 2010/035452 A1 cites, as an exemplary imidazole curing accelerator, 2,4-diamino-6-[2′-undecylimidazolyl-(1′)] ethyl-s-triazine.

However, nobody has ever showed an example in which an imidazole compound having a triazine skeleton is actually added to an epoxy resin composition for forming an insulating layer for a metal-clad laminate, for example. The reason is that people take it granted that although an imidazole compound does have the capability of accelerating curing of an epoxy resin, the curing accelerating capability of an imidazole compound having a triazine skeleton should be too little to put the capability into practical use. That is why it has been practically hard to conceive the idea of actually using a resin composition containing an imidazole compound having a triazine skeleton.

In spite of these circumstances, the present inventors conceived an innovative, inventive concept of using a resin composition containing an imidazole compound having a triazine skeleton to form an insulating layer for a metal-clad laminate and a printed wiring board. In addition, the present inventors also discovered that a cured product of such a resin composition is able to have so high a glass transition temperature that using such a resin composition should allow an insulating layer with high thermal resistance to be formed, thus achieving one of significant advantages of our invention over the known art.

The epoxy resin as Component (A) may contain at least one compound selected from the group consisting of naphthalene type epoxy resins; cresol novolac type epoxy resins; bisphenol A type epoxy resins; bisphenol F type epoxy resins; bisphenol S type epoxy resins; phenol novolac type epoxy resins; alkyl phenol novolac type epoxy resins; aralkyl type epoxy 5 resins; biphenol type epoxy resins; dicyclopentadiene type epoxy resins; epoxidized condensation products of a phenolic compound and an aromatic aldehyde having a phenolic hydroxyl group; triglycidyl isocyanurate; and alicyclic epoxy resins.

The epoxy resin as Component (A) suitably contains a phenol novolac type epoxy resin, among other things. When the resin composition contains the phenol novolac type epoxy resin along with the imidazole compound having a triazine skeleton, as Component (C), the cured product of the resin composition is able to have a particularly high glass transition temperature.

The epoxy resin as Component (A) suitably has an epoxy equivalent weight of 200 or more. This allows the cured product to have particularly high thermal stability.

The phenolic compound as Component (B) is a curing agent for the epoxy resin as Component (A). The phenolic compound as Component (B) may contain at least one compound selected from the group consisting of: tetrakis phenol resins; novolac phenolic resins; naphthalene type phenol resins; cresol novolac resins; aromatic hydrocarbon formaldehyde resin-modified phenol resins; dicyclopentadiene phenol added type resins; phenol aralkyl resins; cresol aralkyl resins; naphthol aralkyl resins; biphenyl-modified phenol aralkyl resins; phenol trimethylol methane resins; tetraphenylol ethane resins; naphthol novolac resins; naphthol-phenol co-condensed novolac resins; naphthol-cresol co-condensed novolac resins; biphenyl-modified phenol resins; amino triazine-modified phenol resins; biphenol; glyoxal tetraphenol resins; bisphenol A novolac resins; and bisphenol F novolac resins.

The phenolic compound as Component (B) suitably contains a tetrakis phenol resin, among other things. When the resin composition contains a phenolic compound containing a tetrakis phenol resin as Component (B) along with the imidazole compound having a triazine skeleton, as Component (C), the cured product of the resin composition is able to have a particularly high glass transition temperature. It is particularly recommended that the epoxy resin as Component (A) contain a phenol novolac type epoxy resin and the phenolic compound as Component (B) contain a tetrakis phenol resin.

The phenolic compound as Component (B) suitably has a hydroxyl equivalent weight of 150 or more. This allows the cured product to have particularly excellent thermal stability.

The equivalent weight ratio of the epoxy resin as Component (A) to the phenolic compound as Component (B) suitably falls within the range from 0.8:1.2 to 1.2:0.8.

As described above, the resin composition contains, as Component (C), an imidazole compound having a triazine skeleton. This allows a cured product of the resin composition to have a high glass transition temperature, which may be as high as 260° C. or an even higher temperature. This allows the insulating layer including a cured product of the resin composition to have excellent thermal resistance. In addition, this also allows the insulating layer including the cured product of the resin composition to have the ability to make highly close contact with the metal layer.

The imidazole compound as Component (C) may contain, for example, 2,4-diamino-6-[2′-ethyl-4′-meth-4′-methylimidazolyl-(1′)] ethyl-s-triazine. The imidazole compound as Component (C) suitably contains 2,4-diamino-6-[2′-ethyl-4′-methylimidazolyl-(1′)]ethyl-s-triazine, among other things. This allows the cured product of the resin composition to have a particularly high glass transition temperature, and also allows an insulating layer including the cured product to exhibit particularly excellent thermal resistance.

In the resin composition, the ratio of the imidazole compound as Component (C) to the sum of the epoxy resin as Component (A) and the phenolic compound as Component (B) suitably falls within the range from 0.02% by mass to 1% by mass. Setting the ratio at a value equal to or greater than 0.02% by mass allows the cured product to have a particularly high glass transition temperature. In addition, setting the ratio at a value equal to or less than 1% by mass reduces the chances of, even when the resin composition, containing a solvent, is stored, components of the resin composition coagulating together. That is to say, this allows the resin composition to have good varnish storage stability. In addition, this also allows the insulating layer to have good solder heat resistance. Note that the varnish storage stability may be evaluated by the method to be described later with respect to specific examples.

Optionally, the resin composition may contain an inorganic filler. The inorganic filler may contain at least one component selected from the group consisting of: silica; barium sulfate; silicon oxide powder; crushed silica; calcined talc; barium titanate; titanium oxide; clay; alumina; mica; boehmite; zinc borate and zinc stannate; and various metals oxides and metal hydrates other than these.

The resin composition containing an inorganic filler allows the insulating layer including the cured product of the resin composition to have a lower linear expansion coefficient. This reduces the deformation (such as warp) of a laminate and printed wiring board including the insulating layer. The content of the inorganic filler suitably accounts for 80% by mass or less, and more suitably falls within the range from 10% by mass to 80% by mass of; the entire resin composition.

The resin composition may contain a solvent. The solvent includes at least one component selected from the group consisting of acetone, ketone solvents such as methyl ethyl ketone and cyclohexanone, aromatic solvents such as toluene and xylene, and a nitrogen-containing solvent such as dimethyl formamide.

Optionally, the resin composition may contain various additional components other than these. For example, the resin composition may contain a light stabilizer, a viscosity modifier, and/or a flame retardant.

Next, the prepreg will be described.

The prepreg includes a fibrous base member and a dried or semi-cured product of the resin composition impregnated into the fibrous base member.

The fibrous base member may be a woven fabric of an inorganic fiber such as glass fiber, a non-woven fabric of an inorganic fiber, a piece of aramid cloth, a piece of polyester cloth, or a piece of paper. The fibrous base member is suitably a woven fabric of glass, i.e., a piece of glass cloth.

To fabricate a prepreg, for example, first, the resin composition is impregnated into the fibrous base member by a known method such as dipping method or application method.

Next, the resin composition is heated to be dried or semi-cured. The heating may be conducted at a temperature falling within the range from 120° C. to 190° C. and for a duration falling within the range from 3 to 15 minutes, for example. However, this is only an example and should not be construed as limiting. This allows a prepreg to be fabricated.

Next, a metal-clad laminate will be described.

The metal-clad laminate includes: an insulating layer; and a metal layer stacked on the insulating layer. The insulating layer includes a cured product of the resin composition described above.

The metal-clad laminate may include two metal layers, which may be respectively stacked on one surface, and the opposite surface, of the insulating layer. Alternatively, the metal-clad laminate may include a single metal layer, which may be stacked on one surface of the insulating layer.

The cured product of the resin composition is able to have a high glass transition temperature, thus allowing the metal-clad laminate to have excellent thermal resistance. In addition, in this metal-clad laminate, the metal layer is able to achieve a high peel strength with respect to the insulating layer.

The cured product may be formed by, for example, heating the resin composition, a dried product of the resin composition, or a semi-cured product of the resin composition.

When the resin composition is heated, the highest heating temperature is suitably equal to or higher than 260° C. This allows a particularly high glass transition temperature and a particularly high peel strength to be achieved. The highest heating temperature more suitably falls within the range from 260° C. to 400° C. and even more suitably falls within the range from 280° C. to 320° C.

The temperature increase rate from the initial temperature at which the resin composition starts to be heated to the highest heating temperature is suitably equal to or higher than 2° C./sec. This allows the cured product to have a particularly high glass transition temperature. The temperature increase rate more suitably falls within the range from 2° C./sec to 8° C./sec and even more suitably falls within the range from 3° C./sec to 5° C./sec.

Next, an exemplary method for fabricating the metal-clad laminate will be described.

A layered structure is formed by overlaying a sheet of metal foil over either the prepreg described above or a stack of a plurality of such prepregs. If the metal-clad laminate includes two metal layers, then a layered structure is formed by respectively overlaying two sheets of metal foil on on one surface, and the opposite surface, of the prepreg or the stack of a plurality of prepregs. On the other hand, if the metal-clad laminate includes only one metal layer, then a layered structure is formed by overlaying a sheet of metal foil over one surface of the prepreg or the stack of a plurality of prepregs. Thermally pressing the layered structure allows an insulating layer including the fibrous base member and the cured product of the resin composition and a metal layer made of the metal foil to be formed. In this manner, a metal-clad laminate may be fabricated.

The cured product included in the insulating layer of this metal-clad laminate is able to have a high glass transition temperature, which may be as high as 260° C. or an even higher temperature. This allows the metal-clad laminate to have excellent thermal resistance.

In this metal-clad laminate, the metal layer is allowed to achieve a high peel strength, which may be 4 N/cm or more, with respect to the insulating layer. The peel strength may be measured by the method to be described later with respect to specific examples.

The conditions for thermally pressing the layered structure include the highest heating temperature, a pressing pressure, and a heating duration.

The highest heating temperature is suitably equal to or higher than 260° C. as described above, more suitably falls within the range from 260° C. to 400° C., and even more suitably falls within the range from 280° C. to 320° C. The temperature increase rate from the initial temperature at which the laminate starts to be thermally pressed to the highest heating temperature is suitably equal to or higher than 2° C./sec, more suitably falls within the range from 2° C./sec to 8° C./sec, and even more suitably falls within the range from 3° C./sec to 5° C./sec.

The pressing pressure suitably falls within the range from 0.5 MPa to 5 MPa, for example. This allows a particularly high glass transition temperature and a particularly high peel strength to be achieved. The pressing pressure more suitably falls within the range from 0.5 MPa to 5 MPa, and even more suitably falls within the range from 2 MPa to 4 MPa.

The heating duration may fall within the range from 1.5 to 6 minutes, and suitably falls within the range from 2.4 to 4 minutes for the following reasons. Specifically, if the heating duration were less than 1.5 minutes, the curing reaction would not be completed, thus possibly causing a decline in the properties of the cured product and making it difficult to obtain a cured product having a glass transition point of 260° C. On the other hand, if the heating were conducted at 260° C. for more than 6 minutes, then the decomposition reaction would advance so much as to possibly cause a decline in the properties of the cured product.

Note that the condition for thermally pressing the layered structure affects the glass transition temperature of the insulating layer and the peel strength of the metal layer with respect to the insulating layer. Thus, according to this embodiment, the condition for thermally pressing the layered structure determines the structure or properties of the laminate. Nevertheless, even though the present inventors analyzed multiple types of insulating layers that were formed by thermally pressing the layered structure under respectively different conditions, the present inventors could not find any significant difference between them. Therefore, although the insulating layer has a structure or properties derived from the condition for thermally pressing the layered structure, it is impossible to define that structure or properties in explicit terms.

Next, the printed wiring board will be described.

The printed wiring board includes an insulating layer, and conductor wiring laid on top of the insulating layer. The insulating layer includes a cured product of the resin composition.

The printed wiring board may include two conductor wiring layers, which may be respectively laid on one surface, and the opposite surface, of the insulating layer. Alternatively, the printed wiring board may include a single conductor wiring layer, which may be stacked on one surface of the insulating layer.

The cured product of the resin composition is able to have a high glass transition temperature, which in turns allows the printed wiring board to have excellent thermal resistance.

Furthermore, in this printed wiring board, the conductor wiring is also able to achieve a high peel strength with respect to the insulating layer.

The printed wiring board may be fabricated by forming conductor wiring through patterning, by photolithography, for example, the metal layer of the metal-clad laminate described above.

The printed wiring board may be a multi-layer printed wiring board including a plurality of insulating layers and a plurality of conductor wiring layers. In that case, at least one of the plurality of insulating layers may contain the cured product of the resin composition described above.

### EXAMPLES

1. Preparation of Resin Composition and Fabrication of Metal-Clad Laminate

A resin composition was prepared by mixing together respective components shown in the “composition” column of Table 1.

A prepreg was fabricated by impregnating the resin composition into a piece of glass cloth (having a thickness of 95 pun; product number 2116 manufactured by Nitto Boseki Co., Ltd.) and then heating the glass cloth impregnated with the resin composition at 130° C. for 3 minutes.

A layered structure was formed by overlaying a sheet of copper foil (having a thickness of 18 μm; product number 3EC-VLP manufactured by Mitsui Mining and Smelting Co., Ltd.) on each of one surface, and the opposite surface, of the prepreg. A metal-clad laminate was fabricated by thermally pressing the layered structure. The temperature increase rate from the initial temperature at which the layered structures started to be heated to the highest temperature while the layered structure was thermally pressed, the highest heating temperature, the pressing pressure, and the heating duration are as shown in the “thermal pressing condition” column in Table 1.

Specifics of the components shown in Table 1 are:
Phenol novolac type epoxy resin: EPPN-502H manufactured by Nippon Kayaku Co., Ltd.;
Bisphenol A type epoxy resin: RE-310S manufactured by Nippon Kayaku Co., Ltd.;
Phenol resin #1: biphenyl aralkyl type phenol resin: MEH 7851-4H manufactured by Meiwa Plastic Industries, Ltd.;
Phenol resin #2: tetrakis phenol resin: MEH 7600-4H manufactured by Meiwa Plastic Industries, Ltd.;
1-cyanoethyl-2-methyl imidazole: 2MZ-CN manufactured by Shikoku Chemicals Corporation;
2-ethyl-4-methyl imidazole: 2E4MZ manufactured by Shikoku Chemicals Corporation;
2,4-diamino-6-[2′-ethyl-4′-methylimidazolyl-(1′)]-ethyl-s-triazine: 2E4MZ-A manufactured by Shikoku Chemicals Corporation;
Spherical silica: SC-205OMTX manufactured by Admatecs; and
Solvent: methyl ethyl ketone.

2. Evaluation Test

The metal-clad laminate was subjected to an evaluation test in the following manner. The results are summarized in Table 1:

(1) Peel Strength

The peel strength of the metal foil (copper foil) with respect to the insulating layer in the metal-clad laminate was measured. The measurement was carried out in compliance with JIS C6481.

(2) Glass Transition Temperature

The glass transition temperature of the cured product included in the insulating layer of the metal-clad laminate was measured by dynamic mechanical analysis. The analysis was carried out using, as a measuring instrument, a viscoelasticity spectrometer (DMS100) manufactured by Seiko Instruments, Inc. to measure tan δ of a bending module under the conditions including a frequency of 10 Hz, a temperature increase rate of 5° C./min, and at temperatures falling within the range from room temperature to 340° C. The temperature at which tan δ reached a local maximum was defined as the glass transition temperature.

(3) Varnish Storage Stability

After having been left at room temperature for 30 days, the resin composition had its degree of transparency checked with the eyes. When found transparent, the resin composition was rated “A.” On the other hand, when found somewhat muddy, the resin composition was rated “B.”

TABLE 1

| | | Examples | | | | | | | | | |
|---|---|---|---|---|---|---|---|---|---|---|---|
| | | 1 | 2 | 3 | 4 | 5 | 6 | 7 | 8 | 9 | 10 |
| Composition | Phenol novolac type epoxy resin | 62 | 62 | 62 | 62 | 62 | 62 | 62 | 62 | 62 | 62 |
| (parts by | Bisphenol A type epoxy resin | 0 | 0 | 0 | 0 | 0 | 0 | 0 | 0 | 0 | 0 |
| mass) | Phenol resin #1 | 0 | 0 | 0 | 0 | 0 | 0 | 0 | 0 | 0 | 0 |
| | Phenol resin #2 | 38 | 38 | 38 | 38 | 38 | 38 | 38 | 38 | 38 | 38 |
| | 1-cyanoethyl-2-methylimidazole | 0 | 0 | 0 | 0 | 0 | 0 | 0 | 0 | 0 | 0 |
| | 2-ethyl-4-methylimidazole | 0 | 0 | 0 | 0 | 0 | 0 | 0 | 0 | 0 | 0 |
| | 2,4-diamino-6-[2′-ethyl-4′- | 0.02 | 0.20 | 1.00 | 0.20 | 0.20 | 0.20 | 0.20 | 0.20 | 0.20 | 0.20 |
| | methylimidazolyl-(1′)]-ethyl-s-triazine | | | | | | | | | | |
| | Spherical silica | 50 | 50 | 50 | 50 | 50 | 50 | 50 | 50 | 50 | 50 |
| | Solvent | 80 | 80 | 80 | 80 | 80 | 80 | 80 | 80 | 80 | 80 |
| Thermal | Temperature increase rate (° C./sec) | 4 | 4 | 4 | 8 | 2 | 4 | 4 | 4 | 4 | 4 |
| pressing | Highest heating temperature (° C.) | 280 | 280 | 280 | 280 | 280 | 260 | 400 | 280 | 280 | 280 |
| Condition | Pressing pressure (MPa) | 3 | 3 | 3 | 3 | 3 | 3 | 3 | 0.5 | 5 | 3 |
| | Heating duration (min) | 3 | 3 | 3 | 3 | 3 | 3 | 3 | 3 | 3 | 6 |
| Evaluation | Glass transition temperature (° C.) | 260 | 290 | 291 | 290 | 288 | 270 | 292 | 290 | 290 | 290 |
| | Peel strength (N/cm) | 4.5 | 5.1 | 5.2 | 5.1 | 4.8 | 4.9 | 5.1 | 4.7 | 5.1 | 5.1 |
| | Varnish storage stability | A | A | A | A | A | A | A | A | A | A |

TABLE 2

| | | Examples | | | | | Comparative examples | | | Reference |
|---|---|---|---|---|---|---|---|---|---|---|
| | | 11 | 12 | 13 | 14 | 15 | 1 | 3 | 4 | example |
| Composition | Phenol novolac type epoxy resin | 62 | 43 | 0 | 0 | 62 | 62 | 62 | 0 | 62 |
| (parts by | Bisphenol A type epoxy resin | 0 | 0 | 64 | 47 | 0 | 0 | 0 | 47 | 0 |
| mass) | Phenol resin #1 | 0 | 57 | 0 | 53 | 0 | 0 | 0 | 53 | 0 |
| | Phenol resin #2 | 38 | 0 | 36 | 0 | 38 | 38 | 38 | 0 | 38 |
| | 1-cyanoethyl-2-methylimidazole | 0 | 0 | 0 | 0 | 0 | 0 | 0 | 0.50 | 0 |
| | 2-ethyl-4-methylimidazole | 0 | 0 | 0 | 0 | 0 | 0.20 | 0.20 | 0 | 0 |
| | 2,4-diamino-6-[2′-ethyl-4′- | 0.20 | 0.20 | 0.20 | 0.20 | 10.0 | 0 | 0 | 0 | 0.20 |
| | methylimidazolyl-(1′)]-ethyl-s-triazine | | | | | | | | | |
| | Spherical silica | 50 | 50 | 50 | 50 | 50 | 50 | 50 | 134 | 50 |
| | Solvent | 80 | 80 | 80 | 80 | 80 | 80 | 80 | 80 | 80 |
| Thermal | Temperature increase rate (° C./sec) | 4 | 4 | 4 | 4 | 4 | 4 | 0.03 | 0.03 | 0.03 |
| pressing | Highest heating temperature (° C.) | 280 | 280 | 280 | 280 | 280 | 300 | 180 | 180 | 180 |
| Condition | Pressing pressure (MPa) | 3 | 3 | 3 | 3 | 3 | 3 | 3 | 3 | 3 |
| | Heating duration (min) | 1.5 | 3 | 3 | 3 | 3 | 3 | 30 | 30 | 30 |
| Evaluation | Glass transition temperature (° C.) | 265 | 265 | 265 | 260 | 291 | 210 | 210 | 170 | 140 |
| | Peel strength (N/cm) | 4.7 | 4.6 | 4.6 | 5.0 | 5.2 | 3.8 | 3.8 | 9.0 | 2.7 |
| | Varnish storage stability | A | A | A | A | B | A | A | A | A |

As can be seen from the foregoing description of embodiments, a resin composition according to a first aspect includes: an epoxy resin as Component (A); a phenolic compound as Component (B); and an imidazole compound having a triazine skeleton, as Component (C). A cured product of the resin composition has a glass transition temperature of 260° C. or more. The first aspect allows a resin composition with the ability to turn, when cured, into a cured product with thermal resistance to be obtained.

In a resin composition according to a second aspect, which may be implemented in conjunction with the first aspect, a ratio of the imidazole compound as Component (C) to the sum of the epoxy resin as Component (A) and the phenolic compound as Component (B) falls within a range from 0.02% by mass to 1% by mass. The second aspect allows the cured product to have a particularly high glass transition temperature and also allows the resin composition to have good varnish storage stability. In addition, this also allows, when the insulating layer contains the cured product, the insulating layer to have good solder heat resistance.

A cured product according to a third aspect is obtained by curing a resin composition containing: an epoxy resin as Component (A); a phenolic compound as Component (B); and an imidazole compound having a triazine skeleton, as Component (C), and has a glass transition temperature of 260° C. or more. The third aspect allows a cured product with thermal resistance to be obtained.

A prepreg according to a fourth aspect includes: a fibrous base member; and a dried or semi-cured product of the resin composition of the first or second aspect impregnated into the fibrous base member. The fourth aspect allows a prepreg with the ability to form an insulating layer with thermal resistance to be obtained.

A metal-clad laminate according to a fifth aspect includes; an insulating layer; and a metal layer stacked on the insulating layer. The insulating layer includes a cured product of the resin composition of the first or second aspect or the cured product of the third aspect. The fifth aspect allows the insulating layer of the metal-clad laminate to have thermal resistance and ability to make close contact with the metal layer.

In a metal-clad laminate according to a sixth aspect, which may be implemented in conjunction with the fifth aspect, the cured product is formed by heating the resin composition of the first or second aspect, a dried product thereof; or a semi-cured product thereof; with a highest heating temperature set at 260° C. or more. The sixth aspect allows the insulating layer to have particularly high thermal resistance and ability to make highly close contact with the metal layer.

In a metal-clad laminate according to a seventh aspect, which may be implemented in conjunction with the sixth aspect, when the resin composition, the dried product thereof; or the semi-cured product thereof is heated, a temperature increase rate is 2° C./sec or more from an initial temperature when the resin composition, the dried product, or the semi-cured product starts to be heated to the highest heating temperature. The seventh aspect allows the insulating layer to have particularly high thermal resistance.

In a metal-clad laminate according to an eighth aspect, which may be implemented in conjunction with any one of the fifth to seventh aspects, a peel strength of the metal layer with respect to the insulating layer is 4 N/cm or more. The eighth aspect allows the insulating layer to have ability to make highly close contact with the metal layer.

A printed wiring board according to a ninth aspect includes: an insulating layer; and conductor wiring laid on top of the insulating layer. The insulating layer includes a cured product of the resin composition of the first or second aspect or the cured product of the third aspect. The ninth aspect allows the insulating layer of the printed wiring board to have thermal resistance and ability to make close contact with the conductor wiring.

A method for fabricating a metal-clad laminate according to a tenth aspect includes: forming a layered structure by overlaying a sheet of metallic foil over a prepreg including: a fibrous base member; and a dried or semi-cured product of a resin composition impregnated into the fibrous base member; and forming an insulating layer including the fibrous base member and the cured product of the resin composition and a metal layer of the metallic foil by thermally pressing the layered structure. The resin composition includes: an epoxy resin as Component (A); a phenolic compound as Component (B); and an imidazole compound having a triazine skeleton, as Component (C). A highest heating temperature when the layered structure is thermally pressed is equal to or higher than 280° C. The tenth aspect allows the insulating layer of the metal-clad laminate to have thermal resistance and ability to make close contact with the metal layer.

In a method for fabricating a metal-clad laminate according to an eleventh aspect, thermally pressing the layered structure includes increasing the temperature at a rate of 2° C./sec or more from an initial temperature at which the layered structure starts to be heated to the highest heating temperature. The eleventh aspect allows the insulating layer to have particularly high thermal resistance.

1. A resin composition comprising:
an epoxy resin as Component (A);
a phenolic compound as Component (B); and
an imidazole compound having a triazine skeleton, as Component (C),
a cured product of the resin composition having a glass transition temperature of 260° C. or more.

2. The resin composition of claim 1, wherein
a ratio of the imidazole compound as Component (C) to the sum of the epoxy resin as Component (A) and the phenolic compound as Component (B) falls within a range from 0.02% by mass to 1% by mass.

3. A prepreg comprising:
a fibrous base member; and
a dried or semi-cured product of the resin composition of claim 1 impregnated into the fibrous base member.

4. A metal-clad laminate comprising:
an insulating layer; and
a metal layer stacked on the insulating layer,
the insulating layer including a cured product of the resin composition of claim 1.

5. The metal-clad laminate of claim 4, wherein
the cured product is formed by heating the resin composition of claim 1, a dried product thereof, or a semi-cured product thereof, with a highest heating temperature set at 260° C. or more.

6. The metal-clad laminate of claim 5, wherein
when the resin composition, the dried product thereof, or the semi-cured product thereof is heated, a temperature increase rate is 2° C./sec or more from an initial temperature when the resin composition, the dried product, or the semi-cured product starts to be heated to the highest heating temperature.

7. The metal-clad laminate of claim 4, wherein
a peel strength of the metal layer with respect to the insulating layer is 4 N/cm or more.

8. A printed wiring board comprising:
an insulating layer; and
conductor wiring laid on top of the insulating layer,
the insulating layer including a cured product of the resin composition of claim 1.

9. A method for fabricating a metal-clad laminate, the method comprising:
forming a layered structure by overlaying a sheet of metallic foil over a prepreg, the prepreg including: a fibrous base member; and a dried or semi-cured product of a resin composition impregnated into the fibrous base member; and
forming an insulating layer including the fibrous base member and the cured product of the resin composition and a metal layer of the metallic foil by thermally pressing the layered structure,
the resin composition including:
an epoxy resin as Component (A);
a phenolic compound as Component (B); and
an imidazole compound having a triazine skeleton, as Component (C), a highest heating temperature when the layered structure is thermally pressed being equal to or higher than 280° C.

10. The method of claim 9, wherein
thermally pressing the layered structure includes increasing the temperature at a rate of 2° C./sec or more from an initial temperature at which the layered structure starts to be heated to the highest heating temperature.
